(19) United States
(12) Patent Application Publication
(10) Pub. No.: US 2026/0155788 A1
(43) Pub. Date: Jun. 4, 2026

(54) QUARTER-WAVE IMPEDANCE INVERTER IN HIGHLY COMPACT INTEGRATED PASSIVE DEVICES

(71) Applicant: SKYWORKS SOLUTIONS, INC., Irvine, CA (US)

(72) Inventors: Jun Celis Jadormio, Marlborough, MA (US); Raymond Mitchell Waugh, Tewksbury, MA (US); Eric J. Marsan, Walpole, MA (US)

(21) Appl. No.: 19/170,958

(22) Filed: Apr. 4, 2025

Related U.S. Application Data
(60) Provisional application No. 63/574,780, filed on Apr. 4, 2024.

(51) Int. Cl. H03F 1/02; H03F 1/56; H03F 3/60

(52) U.S. Cl. CPC H03F 1/0288; H03F 1/565; H03F 3/602; H03F 2200/451

(57) ABSTRACT

Technologies are disclosed that implement impedance inversion using a combination of transmission lines and lump elements to provide a targeted transformation or inversion. These impedance inverters or transformers use a hybrid approach, combining transmission lines with lump elements, where the transmission lines provide a first fraction of a targeted overall phase shift and the lump elements provide a second fraction of the targeted overall phase shift so that the combination of the elements provides the targeted overall phase shift. The first fraction can be less than 50% and the second fraction can be greater than 50% so that the phase shift is not evenly divided between the components of the hybrid impedance inverters.

### CROSS-REFERENCE TO RELATED APPLICATIONS

This application claims priority to U.S. Provisional Application No. 63/574,780 filed Apr. 4, 2024 and entitled “QUARTER-WAVE IMPEDANCE INVERTER IN HIGHLY COMPACT INTEGRATED PASSIVE DEVICES,” which is expressly incorporated by reference herein in its entirety.

### BACKGROUND

### Field

The present disclosure generally relates to quarter-wave impedance inverters and Doherty power amplifier configurations.

### Description of Related Art

Wireless devices employ a variety of amplifiers to amplify signals. These wireless devices employ power amplifiers to amplify signals prior to transmission. A variety of power amplifier architectures may be employed. One example is a Doherty power amplifier which may be particularly beneficial in wireless devices with high peak to average power ratio (PAPR) modulation signals.

### SUMMARY

According to a number of implementations, the present disclosure relates to a Doherty power amplifier for amplifying radio-frequency (RF) signals. The Doherty power amplifier includes a splitter configured to receive an input signal and to provide a first signal associated with the input signal on a carrier amplification path and a second signal associated with the input signal on a peaking amplification path; a carrier amplifier implemented on the carrier amplification path; a peaking amplifier implemented on the peaking amplification path; and a quarter-wave impedance inverter coupled to the peaking amplification path and the carrier amplification path and configured to provide a targeted phase shift to amplified signals, the quarter-wave impedance inverter comprising a first section configured to provide a first portion of the targeted phase shift and a second section configured to provide a second portion of the targeted phase shift, the first section including a transmission line, the second section including lumped elements coupled in series to the transmission line.

In some implementations, the quarter-wave impedance inverter is implemented in a combiner configured to combine amplified signals from the carrier amplification path and amplified signals from the peaking amplification path. In some implementations, the first portion of the targeted phase shift is less than 50% of the targeted phase shift and the second portion of the targeted phase shift is greater than 50% of the targeted phase shift. In some implementations, the first portion of the targeted phase shift is greater than 30% and less than 40% of the targeted phase shift and the second portion of the targeted phase shift is greater than 60% and less than 70% of the targeted phase shift. In some implementations, a sum of the first portion of the targeted phase shift and the second portion of the targeted phase shift is equal to the targeted phase shift. In some implementations, the second section comprises a pi-network, T-network, or a combination of both. In some implementations, the quarter-wave impedance inverter is implemented using integrated passive device technology. In some implementations, the Doherty power amplifier further includes one or more impedance matching networks implemented on the peaking amplification path and one or more impedance matching networks implemented on the carrier amplification path. In some implementations, the quarter-wave impedance inverter is configured to phase shift amplified signals on the peaking amplification path. In some implementations, the quarter-wave impedance inverter is configured to phase shift amplified signals on the carrier amplification path.

According to a number of implementations, the present disclosure relates to a front end module that includes a packaging substrate; and a Doherty power amplifier implemented on the packaging substrate, the Doherty power amplifier configured to amplify radio-frequency (RF) signals, the Doherty power amplifier including: a splitter configured to receive an input signal and to provide a first signal associated with the input signal on a carrier amplification path and a second signal associated with the input signal on a peaking amplification path; a carrier amplifier implemented on the carrier amplification path; a peaking amplifier implemented on the peaking amplification path; and a quarter-wave impedance inverter coupled to the peaking amplification path and the carrier amplification path and configured to provide a targeted phase shift to amplified signals, the quarter-wave impedance inverter comprising a first section configured to provide a first portion of the targeted phase shift and a second section configured to provide a second portion of the targeted phase shift, the first section including a transmission line, the second section including lumped elements coupled in series to the transmission line.

In some implementations, the quarter-wave impedance inverter is implemented in a combiner configured to combine amplified signals from the carrier amplification path and amplified signals from the peaking amplification path. In some implementations, the first portion of the targeted phase shift is less than 50% of the targeted phase shift and the second portion of the targeted phase shift is greater than 50% of the targeted phase shift. In some implementations, the first portion of the targeted phase shift is greater than 30% and less than 40% of the targeted phase shift and the second portion of the targeted phase shift is greater than 60% and less than 70% of the targeted phase shift. In some implementations, a sum of the first portion of the targeted phase shift and the second portion of the targeted phase shift is equal to the targeted phase shift. In some implementations, the second section comprises a pi-network, T-network, or a combination of both. In some implementations, the quarter-wave impedance inverter is implemented using integrated passive device technology.

According to a number of implementations, the present disclosure relates to a wireless device that includes a primary antenna; and a front end module coupled to the primary antenna, the front end module comprising a Doherty power amplifier configured to amplify radio-frequency (RF) signals, the Doherty power amplifier including: a splitter configured to receive an input signal and to provide a first signal associated with the input signal on a carrier amplification path and a second signal associated with the input signal on a peaking amplification path; a carrier amplifier implemented on the carrier amplification path; a peaking amplifier implemented on the peaking amplification path; and a quarter-wave impedance inverter coupled to the peaking amplification path and the carrier amplification path and configured to provide a targeted phase shift to amplified signals, the quarter-wave impedance inverter comprising a first section configured to provide a first portion of the targeted phase shift and a second section configured to provide a second portion of the targeted phase shift, the first section including a transmission line, the second section including lumped elements coupled in series to the transmission line.

In some implementations, the quarter-wave impedance inverter is implemented in a combiner configured to combine amplified signals from the carrier amplification path and amplified signals from the peaking amplification path. In some implementations, the first portion of the targeted phase shift is less than 50% of the targeted phase shift and the second portion of the targeted phase shift is greater than 50% of the targeted phase shift.

For purposes of summarizing the disclosure, certain aspects, advantages and novel features have been described herein. It is to be understood that not necessarily all such advantages may be achieved in accordance with any particular embodiment. Thus, the disclosed embodiments may be carried out in a manner that achieves or optimizes one advantage or group of advantages as taught herein without necessarily achieving other advantages as may be taught or suggested herein.

### BRIEF DESCRIPTION OF THE DRAWINGS

FIG. 1 illustrates a wireless device having a primary antenna and at least one power amplifier that implements a hybrid quarter-wave impedance inverter.

FIG. 2 illustrates a Doherty PA architecture that implements a hybrid quarter-wave impedance inverter in a combiner.

FIG. 3 illustrates an example of a hybrid quarter-wave impedance inverter implemented as part of a Doherty PA architecture, similar to the Doherty PA architecture of FIG. 2.

FIG. 4 illustrates an example of a hybrid quarter-wave impedance inverter, similar to the hybrid quarter-wave impedance inverter of FIG. 3.

FIG. 5 illustrates an example implementation of a hybrid quarter-wave impedance inverter similar to the hybrid quarter-wave impedance inverter of FIG. 4 and the hybrid quarter-wave impedance inverter of FIG. 3.

FIG. 6 illustrates that some or all of the front end configurations can be implemented, wholly or partially, in a module.

FIG. 7 illustrates that some or all of the front end configurations can be implemented, wholly or partially, in an architecture.

FIG. 8 depicts an example wireless device having one or more advantageous features described herein.

### DETAILED DESCRIPTION OF SOME EMBODIMENTS

The headings provided herein, if any, are for convenience only and do not necessarily affect the scope or meaning of the claimed invention.

### Overview

Radio-frequency (RF) applications, such as those implemented in wireless devices, typically use power amplifiers to amplify signals prior to transmission. There exist various power amplifier architectures that may be implemented for such devices. For example, Doherty power amplifier (PA) applications are particularly suited for high peak to average power ratio (PAPR) modulation signals used in various wireless devices (e.g., smart phones and cellular phones). Doherty power amplifiers can provide certain advantages over other designs, such as achieving up to about 10% higher peak power added efficiency (PAE) levels for the same adjacent power level ratio (ACLR) levels. This level of PAE performance can match that of an envelope tracking (ET) PA but with less overall system complexity than for ET PAs.

A quarter-wave impedance inverter is commonly used in a combining network of Doherty PAs. A typical approach is to implement the quarter-wave impedance inverter using microstrip lines that are printed into a multi-layer laminate substrate. However, this approach requires relatively long transmission line traces and has a relatively large footprint on the module or chip where the quarter-wave impedance inverter is implemented. Due at least in part to the relatively large physical structure of the impedance inverter, large parasitic capacitances to ground are generated. Disadvantageously, this results in higher insertion loss, narrow bandwidth response, and difficulty in controlling the characteristic impedance.

Other approaches to providing the quarter-wave impedance inverter use lump elements with inductors and capacitors to create a pi-network, a T-network, or a combination of both. However, in such implementations, it is challenging to control the phase and impedance of the impedance inverter over a wider bandwidth. This is due at least in part to the narrow band nature for quarter-wave inversion. Using lump elements in this manner suffers bandwidth limitations, relatively wide variations in phase shift, and relatively wide variations in the characteristic impedance of the transmission line.

Accordingly, described herein are technologies that implement impedance inversion using a combination of transmission lines and lump elements to provide the targeted transformation or inversion. These impedance inverters or transformers use a hybrid approach, combining transmission lines with lump elements, where the transmission lines provide a first fraction of a targeted overall phase shift and the lump elements provide a second fraction of the targeted overall phase shift so that the combination of the elements provides the targeted overall phase shift. In various implementations of the disclosed hybrid impedance inverters, the first fraction is less than 50% and the second fraction is greater than 50% so that the phase shift is not evenly divided between the components of the hybrid impedance inverters.

The disclosed impedance transformers can be implemented as quarter-wave impedance transformers in a Doherty PA architecture. The quarter-wave impedance transformers split the phase shift into two sections, the first section of the phase shift provided by a transmission line and the second section of the phase shift provided by lump elements, such as a lumped element pi-network, T-network, or a combination of both. The disclosed impedance transformers can be implemented using flip chip integrated passive device (IPD) technology. In certain implementations, the first section comprising the transmission line provides about 35% of the total phase shift of the quarter-wave impedance transformer. In such implementations, because the transmission line is shorter in length than impedance transformers that solely use the transmission line (or do not use lumped elements in combination with the transmission line), the first section produces lower parasitic capacitance. This, in turn, increases the bandwidth over which the transformer can acceptably operate, reduces insertion loss, and improves the impedance variation for wider bandwidth applications. In various implementations, the second section comprising the lumped elements (e.g., a lumped element pi-network, T-network, or a combination of both) provides about 65% of the total phase shift of the quarter-wave impedance transformer. Due at least in part to the second section not being a 90-degree phase shifter network, the phase inverter has less sensitivity related to its phase and impedance variation. Consequently, the second section helps to improve phase variation through the quarter-wave impedance transformer, reduces insertion loss, and improves control over the characteristic impedance of the network.

The transmission line section and the lumped element section combine to form a complete quarter-wave impedance transformer or inverter that can be advantageously implemented in an IPD. In such implementations, there are additional advantages provided by the disclosed transformers. For example, printing a transmission line on silicon allows for superior control over the width of the transmission line compared to typical printed circuit boards. Furthermore, the substrate has superior thermal conductivity that helps to reduce dielectric loss and improves the thermal handling capability of the transformer.

Thus, the hybrid transformer architectures described herein split a quarter-wave impedance inverter into two sections: the transmission line and the lumped element section (e.g., a pi-network, T-network, or a combination of both). The transmission line provides a portion of the phase shift while the lumped elements provide the rest of the phase shift. This reduces the length of the transmission line thereby reducing the size of the inverter which reduces the parasitic capacitance and the package size of the Doherty PA. Consequently, there is an improvement in the bandwidth and a reduction in insertion loss. In some implementations, the disclosed impedance inverters are implemented in an IPD. Because of the reduction in size, the disclosed technologies can be implemented in highly compact IPDs. In addition, the overall package size is kept relatively small, reducing size requirements and costs.

Hence, there are a number of advantages provided by the disclosed hybrid inverters or transformers. The disclosed technologies advantageously reduce phase variation in the broadband system. The disclosed technologies also advantageously reduce the sensitivity of the impedance transformer sensitivity to the overmold structure in which it is implemented. For example, there is not a change in the impedance before and after applying the overmold of the laminate. The disclosed technologies advantageously also provide superior control of the impedance in a high-characteristic impedance quarter-wave transformer and provide this superior impedance control in a wider bandwidth system. The disclosed technologies advantageously also reduce insertion loss. The disclosed technologies advantageously also improve thermal handling characteristics of the resulting transformer.

Although the disclosed technologies are described primarily in conjunction with Doherty PAs, it is to be understood that the disclosed technologies can be implemented in a variety of circuits where it is advantageous to have a quarter-wave transformer or impedance inverter. For example, the disclosed technologies can be implemented in splitters, combiners, and the like.

Front End Modules with Doherty PAs Using Hybrid Impedance Inverters

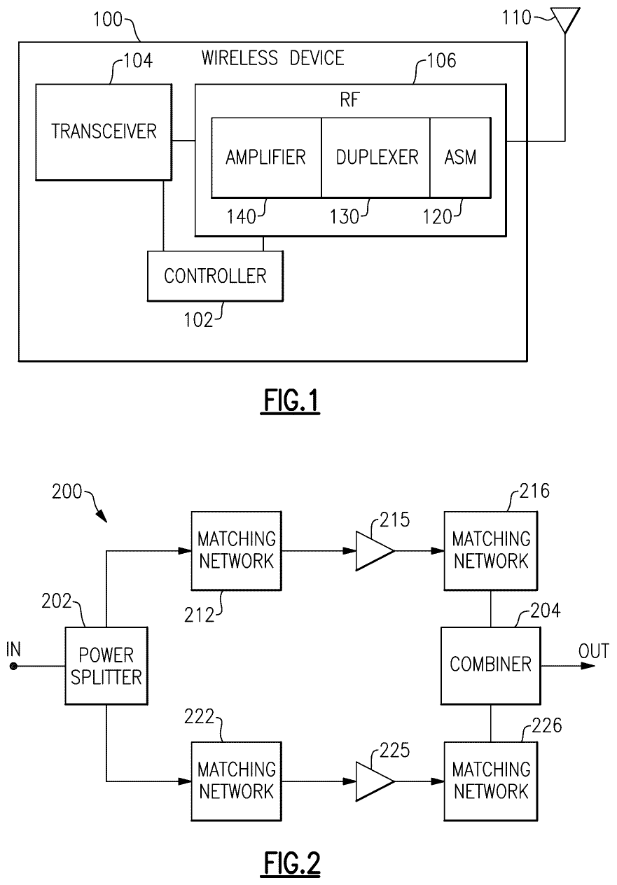

FIG. 1 illustrates a wireless device 100 having a primary antenna 110 and at least one power amplifier that implements a hybrid quarter-wave impedance inverter. The wireless device 100 includes an RF module 106 and a transceiver 104 that may be controlled by a controller 102. The transceiver 104 is configured to convert between analog signals (e.g., radio-frequency (RF) signals) and digital data signals. To that end, the transceiver 104 may include a digital-to-analog converter, an analog-to-digital converter, a local oscillator for modulating or demodulating a baseband analog signal to or from a carrier frequency, a baseband processor that converts between digital samples and data bits (e.g., voice or other types of data), or other components.

The RF module 106 is coupled between the primary antenna 110 and the transceiver 104. Because the RF module 106 may be physically close to the primary antenna 110 to reduce attenuation due to cable loss, the RF module 106 may be referred to as a front end module (FEM). The RF module 106 may perform processing on an analog signal received from the primary antenna 110 for the transceiver 104 or received from the transceiver 104 for transmission via the primary antenna 110. To that end, the RF module 106 may include an antenna switch module (ASM) 120. The RF module also includes one or more duplexers 130, one or more amplifiers 140 (including power amplifiers (PAs) and low noise amplifiers (LNAs)) and may also include band select switches, attenuators, matching circuits, transformers, impedance inverters, and other components. The ASM 120 may be connected to a plurality of duplexers 130 to enable operation across a plurality of frequency bands. The RF module 106 provides a receive path for signals received at the primary antenna 110, the receive path including a signal path from the primary antenna 110, to the ASM 120, to the duplexers 130, to the amplifiers 140, to the transceiver 104. Similarly, the RF module 106 provides a transmit path for signals to be transmitted by the primary antenna 110, the transmit path including a signal path from the transceiver 104, to the amplifiers 140, to the duplexers 130, to the ASM 120, and to the primary antenna 110 for transmitting.

The controller 102 can be configured to generate and/or send control signals to other components of the wireless device 100. The controller 102 can be configured to receive signals from other components of the wireless device 100 to process to determine control signals to send to other components. In some embodiments, the controller 102 can be configured to analyze signals or data to determine control signals to send to other components of the wireless device 100.

The RF module 106 is an example of a front end module that incorporates the front end architectures described herein, and in particular the Doherty PA architectures disclosed herein. These Doherty PA architectures include hybrid quarter-wave impedance inverters to provide superior phase shift performance in a relatively small package, such as an integrated passive device (IPD). Characteristics of the amplifiers 140, duplexers 130, and ASM 120 can be tailored to improve amplifier performance, including by implementing hybrid impedance inverters that provide targeted phase shifts, as described herein. In addition, impedance matching and other such components along the receive path may also be tailored to improve amplifier performance.

### Example Doherty Power Amplifier Architecture with Broad Harmonic Termination

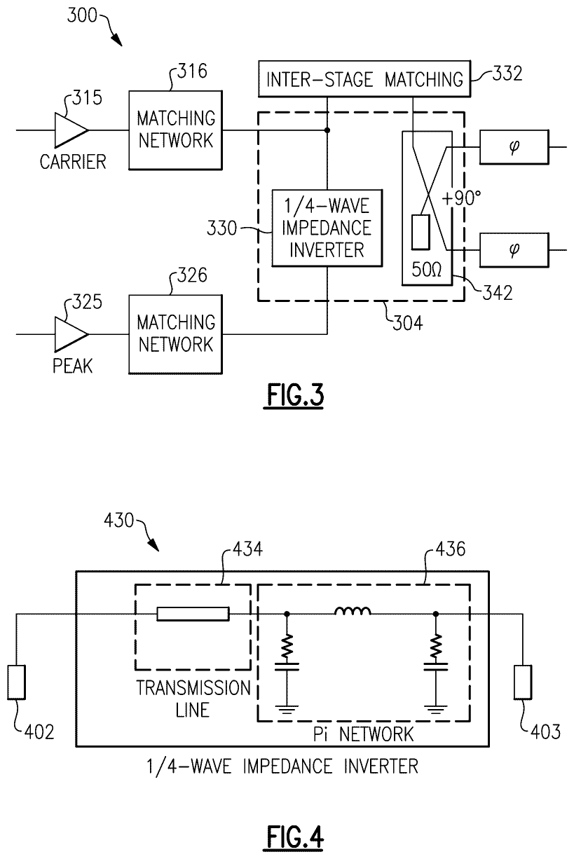

FIG. 2 illustrates a Doherty PA architecture 200 that implements a hybrid quarter-wave impedance inverter in a combiner 204. The Doherty PA architecture 200 includes two amplifier paths, both fed from a power splitter 202. The carrier amplifier 215 is always on while the peaking amplifier 225 remains idle unless the signal moves into a high-power region. In the high-power region, the peaking amplifier 225 turns on and provides additional amplification to support the higher output power. After amplification, the amplified signals are combined at the combiner 204. In addition, there is a first impedance matching network 212 between the carrier amplifier 215 and the power splitter 202, a second impedance matching network 222 between the peaking amplifier 225 and the power splitter 202, a third impedance matching network 216 between the carrier amplifier 215 and the combiner 204, and a fourth impedance matching network 226 between the peaking amplifier 225 and the combiner 204. The Doherty PA architecture 200 also includes an impedance inverter implemented as part of the combiner 204. The impedance inverter is implemented as a hybrid element that combines a transmission line that provides a fraction of a targeted phase shift and lumped elements that provide the remaining portion of the targeted phase shift. This can be done to align the two amplifier paths, for example.

Many modulation techniques maintain amplitude and phase purity. Therefore, to maintain linearity, the carrier amplifier 215 can be operated in Class A, Class B or Class AB. Similarly, the peaking amplifier 225 can be operated in Class C, meaning that the amplifier is only biased on part of the time. Class C can be associated with non-linear operation but because the Doherty PA architecture 200 incorporates the peaking amplifier 225 as an add-on device, linearity is typically maintained at the output. Although the Doherty PA architecture 200 shows two amplifier paths, some designs can use additional peaking amplifiers to improve performance in the high-power region. In addition, although the various examples are described in the context of a Doherty PA architecture, it will be understood that one or more features of the present disclosure can also be implemented in other types of PA systems.

The Doherty PA architecture 200 is shown to include an input port (IN) for receiving an RF signal to be amplified. Such an input RF signal can be partially amplified by a pre-driver amplifier before being divided into a carrier amplification path and a peaking amplification path. Such a division can be achieved by a divider or a power splitter 202.

The carrier amplification path includes the first impedance matching network 212, the carrier amplifier 215, and the third impedance matching network 216. The peaking amplification path includes the second impedance matching network 222, the peaking amplifier 225, and the fourth impedance matching network 226. In some implementations, the carrier amplifier 215 and/or the peaking amplifier 225 each include one or more amplification stages (e.g., a driver stage and an output stage). Although not shown here, bias circuits can be used to bias the carrier amplifier 215 and/or the peaking amplifier 225. The carrier amplification path and the peaking amplification path can be combined by the combiner 204 so as to yield an amplified RF signal at an output port (OUT). In some implementations, at least a portion of the combiner 204 comprises a quarter-wave impedance inverter implemented using IPD technology. The quarter-wave impedance inverter includes a transmission line that provides less than half of a targeted phase shift (e.g., at least 20% and less than 50% of the targeted phase shift) and a lumped element section (e.g., pi-network, T-network, or a combination of both) provides the remaining portion of the targeted phase shift (e.g., greater than 50% and less than or equal to 80% of the targeted phase shift).

In some implementations, the carrier amplifier 215 can be configured to operate in a Class AB mode. In some implementations, the peaking amplifier 225 can be configured to operate in a Class C mode. The different biasing modes can include Class A, Class B, Class AB, Class C, Class D, Class F, Class G, Class I, Class S, Class T, or any other biasing mode. In some implementations, the Doherty PA architecture 200 is based on gallium nitride (GaN) technology.

### Examples of Hybrid Quarter-Wave Impedance Inverters

FIG. 3 illustrates an example of a hybrid quarter-wave impedance inverter 330 implemented as part of a Doherty PA architecture 300, similar to the Doherty PA architecture 200. In some implementations, the hybrid quarter-wave impedance inverter 330 is implemented in a combiner 304, similar to the combiner 204 of FIG. 2. The hybrid quarter-wave impedance inverter 330 splits into two sections to achieve the quarter-wave impedance inversion to combine the signals from a carrier amplifier 315 (similar to the carrier amplifier 215 of FIG. 2) and a peaking amplifier 325 (similar to the peaking amplifier 225 of FIG. 2). The two sections, as described herein, include a transmission line and a lumped element section (e.g., a pi-network, T-network, or a combination of both), the transmission line providing a portion of the phase shift while the lumped element section provides the remaining portion of the phase shift. In addition, there are output matching networks 316, 326 as well as an inter-stage matching network 332 to match impedances from the output of the Doherty PA to the next stage in the processing path. For example, the next stage can include a splitter 342 configured to split the signal for processing in a second amplification path or for other purposes.

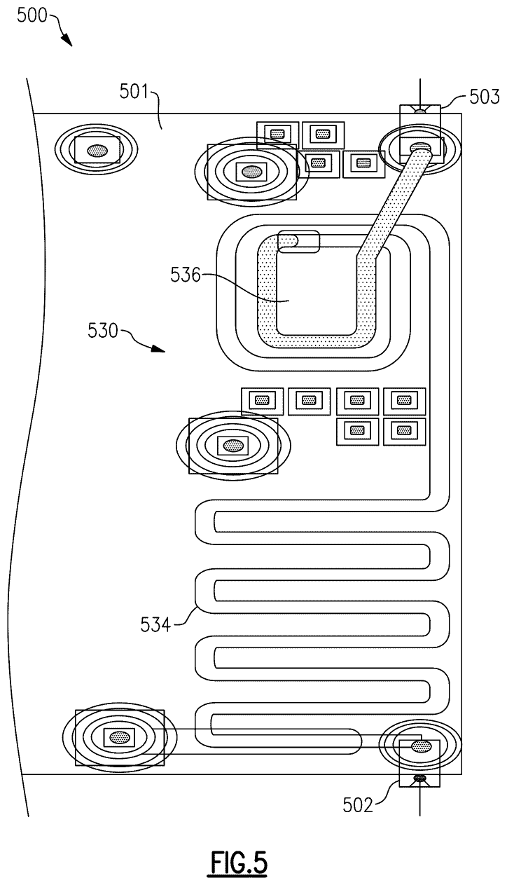

FIG. 4 illustrates an example of a hybrid quarter-wave impedance inverter 430, similar to the hybrid quarter-wave impedance inverter 330 described with reference to FIG. 3. The hybrid quarter-wave impedance inverter 430 includes a first section 434 comprising a transmission line and a second section 436 comprising lumped elements forming a pi-network, T-network, or a combination of both. The hybrid quarter-wave impedance inverter 430 is configured to provide a targeted phase shift. In some implementations, the targeted phase shift is 90 degrees. The first section 434 provides a first portion of the targeted phase shift and the second section 436 provides a second portion of the targeted phase shift. In some implementations, the first portion of the targeted phase shift is less than 50%. For example, the first portion of the targeted phase shift can be at least 20% and less than 50%, at least 30% and less than or equal to about 40%, or about 35% of the targeted phase shift. In some implementations, the second portion of the targeted phase shift is greater than 50%. For example, the first portion of the targeted phase shift can be greater than 50% and less or equal to 80%, at least 60% and less than or equal to about 70%, or about 65% of the targeted phase shift.

The first section 434 and the second section 436 are connected in series between an input 402 and an output 403. The first section 434 comprises a transmission line or a trace implemented on a substrate that has a targeted or characteristic impedance configured to provide the first portion of the targeted phase shift. The second section 436 comprises lumped elements that form a pi-network, T-network, or a combination of both. For the pi-network, the second section 436 can include an inductor between RC shunt circuits coupled to a reference potential node, such as a ground potential.

FIG. 5 illustrates an example implementation of a hybrid quarter-wave impedance inverter 530 similar to the hybrid quarter-wave impedance inverter 430 of FIG. 4 and the hybrid quarter-wave impedance inverter 330 of FIG. 3. The hybrid quarter-wave impedance inverter 530 is implemented using IPD technology, such as on a flip chip 500. The hybrid quarter-wave impedance inverter 530 is implemented on a substrate 501 and includes an input 502 and an output 503 to couple to other components in the architecture (e.g., a Doherty PA architecture, a front end architecture, a wireless device architecture, etc.).

The input 502 is electrically coupled to a transmission line 534 that forms the first portion of the hybrid quarter-wave impedance inverter 530. The transmission line 534 snakes back and forth on the substrate 501 to conserve space. The length of the transmission line 534 is configured to provide a first targeted phase shift for signals propagating across the transmission line 534. In some implementations, the targeted phase shift is less than half of an overall phase shift which may be 90 degrees.

The transmission line 534 is electrically coupled to a lump element network 536 configured to provide a second targeted phase shift for signals propagating through the lump element network 536. In some implementations, the lump element network 536 comprises a pi-network, T-network, or a combination of both. The lump element network 536 can include lump elements such as inductors, capacitors, and resistors that together provide the second targeted phase shift. The output of the lump element network 536 is coupled to the output 503.

The sum of the first targeted phase shift and the second targeted phase shift is configured to be a targeted overall phase shift. The overall phase shift can be targeted to be 90 degrees or it can be targeted to be 180 degrees or another value other than 90 degrees or 180 degrees. The first targeted phase shift can be between at least 20% and less than 50% of the overall phase shift and the second targeted phase shift can be greater than 50% and less than or equal to 80% of the overall phase shift. The first targeted phase shift can be between at least 30% and less than 40% of the overall phase shift and the second targeted phase shift can be greater than 60% and less than or equal to 70% of the overall phase shift. The first targeted phase shift can be about 35% of the overall phase shift and the second targeted phase shift can be about 65% of the overall phase shift.

Because the transmission line 534 utilizes a shorter length than it would if it were to provide the entire overall phase shift, the transmission line 534 produces lower parasitic capacitance which helps to increase the bandwidth and reduce the insertion loss while improving the impedance variation in the wide bandwidth response. Because the lump element network 536 is not a 90-degree phase shifter network, the hybrid quarter-wave impedance inverter 530 is less sensitive to variations in phase and impedance introduced by the lump element network 536. Thus, the lump element network 536 helps to improve phase variation, to reduce insertion loss, and to improve control of the characteristic impedance of the network.

In some implementations, the transmission line 534 and the lump element network 536 combine to build a complete quarter-wave impedance inverter that is implemented in an IPD. In such implementations, additional advantages are realized. For example, printing the transmission line on the silicon substrate of an IPD allows superior control over the width of the transmission line on the substrate 501 relative to a typical PCB-type material. In addition, the overmold laminate has better thermal conductivity that helps to reduce dielectric loss and improve thermal handling capabilities of the hybrid quarter-wave impedance inverter 530. That is, there is not a change in the impedance before and after applying the overmold. Overall, targeted phase shifts are achieved in a smaller package with improved performance over wider bandwidths, such as reduced insertion losses, reduced parasitic capacitances, improved thermal management, reduced phase and impedance variations across the wider bandwidth, reduced dielectric losses, and so forth.

The disclosed hybrid impedance inverters can be implemented at any suitable location in a Doherty PA. For example, the disclosed inverters or transformers can be implemented after the amplifiers and output matching networks, e.g., within a combiner or prior to the combiner. The disclosed inverters can be implemented at the input of a Doherty PA and may be implemented, for example, as part of a splitter for splitting a signal. The disclosed inverters can be implemented between Doherty PA stages where the PA is implemented as a multi-stage PA. In short, the disclosed inverters and transformers can be implemented where it is desirable to implement a combining network with a quarter-wave transformer. The disclosed inverters are particularly advantageous for implementations in smaller packages, such as IPDs. Typically, quarter-wave impedance transformers are relatively large and are implemented in PCBs. In contrast, the disclosed quarter-wave impedance transformers have a reduced footprint such that they can be implemented using IPD technology.

### Examples of Products and Architectures

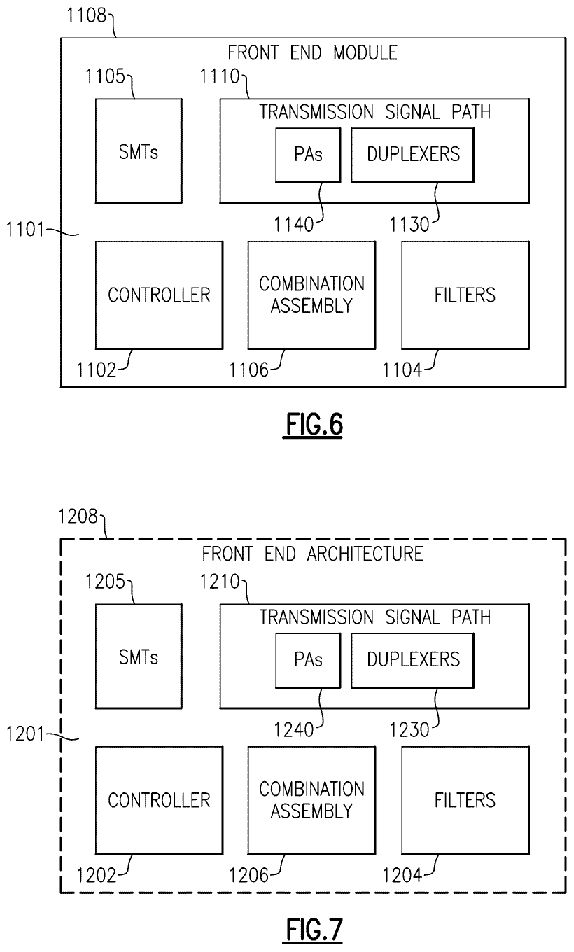

FIG. 6 illustrates that, in some embodiments, some or all of the front end configurations, including some or all of the Doherty PA configurations having combinations of features (e.g., FIGS. 1-5), can be implemented, wholly or partially, in a module. Such a module can be, for example, a front end module (FEM). Such a module can be, for example, a diversity receiver (DRx) FEM. Such a module can be, for example, a multi-input, multi-output (MiMo) module.

In the example of FIG. 6, a module 1108 can include a packaging substrate 1101, and a number of components can be mounted on such a packaging substrate 1101. For example, a controller 1102 (which may include a front end power management integrated circuit [FE-PIMC]), a combination assembly 1106, a transmission signal path 1110 that includes one or more duplexers 1130 and one or more amplifiers 1140 (e.g., PAs), the one or more amplifiers 1140 being configured as described herein to utilize a hybrid quarter-wave impedance inverter to improve performance. A filter bank 1104 (which may include one or more multiplexers) can be mounted and/or implemented on and/or within the packaging substrate 1101. Other components, such as a number of SMT devices 1105, can also be mounted on the packaging substrate 1101. Although all of the various components are depicted as being laid out on the packaging substrate 1101, it will be understood that some component(s) can be implemented over other component(s).

In some embodiments, the transmission signal path 1110 can be implemented on a semiconductor die that is in turn mounted on the packaging substrate 1101. In further embodiments, the duplexers 1130 and/or the one or more amplifiers 1140 can be implemented on a single semiconductor die that is mounted on the packaging substrate 1101. In various embodiments, one or more of the plurality of duplexers 1130 or the one or more amplifiers 1140 are implemented on a semiconductor die with one or more of the other components mounted on a separate semiconductor die or on the packaging substrate 1101.

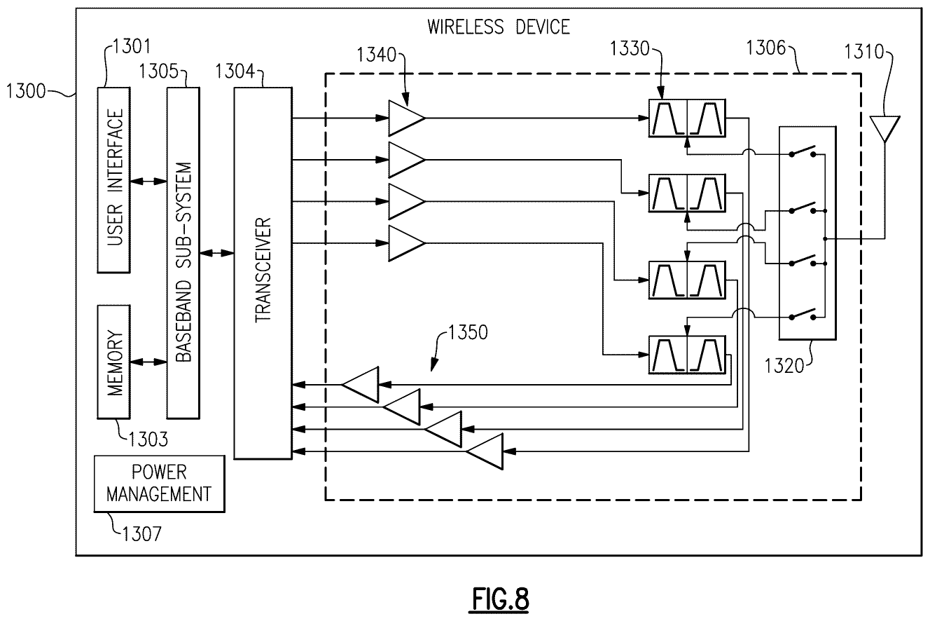

FIG. 7 shows that, in some embodiments, some or all of the front end configurations, including some or all of the Doherty PA configurations having combinations of features (e.g., FIGS. 1-5), can be implemented, wholly or partially, in an architecture. Such an architecture may include one or more modules, and can be configured to provide front end functionality.

In the example of FIG. 7, an architecture 1208 can include a controller 1202 (which may include a front end power management integrated circuit [FE-PIMC]), a combination assembly 1206, a transmission signal path 1210 that includes one or more duplexers 1230 and one or more amplifiers 1240 (e.g., PAs), the one or more amplifiers 1240 being configured as described herein to utilize a hybrid quarter-wave impedance inverter to improve performance. A filter bank 1204 (which may include one or more multiplexers) can be mounted and/or implemented on and/or within the packaging substrate 1201. Other components, such as a number of SMT devices 1205, can also be implemented in the architecture 1208.

In some implementations, a device and/or a circuit having one or more features described herein can be included in an RF electronic device such as a wireless device. Such a device and/or a circuit can be implemented directly in the wireless device, in a modular form as described herein, or in some combination thereof. In some embodiments, such a wireless device can include, for example, a cellular phone, a smart-phone, a hand-held wireless device with or without phone functionality, a wireless tablet, etc.

FIG. 8 depicts an example wireless device 1300 having one or more advantageous features described herein. In the context of one or more modules having one or more features as described herein, such modules can be generally depicted by a dashed box (such as a module 1306 which can be implemented as, for example, a front end module).

Referring to FIG. 8, power amplifiers (PAs) 1340 can receive their respective RF signals from a transceiver 1304 that can be configured and operated to generate RF signals to be amplified and transmitted, and to process received signals. The transceiver 1304 is shown to interact with a baseband sub-system 1305 that is configured to provide conversion between data and/or voice signals suitable for a user and RF signals suitable for the transceiver 1304. The transceiver 1304 can also be in communication with a power management component 1307 that is configured to manage power for the operation of the wireless device 1300. Such power management can also control operations of the baseband sub-system 1305 and the module 1306.

The baseband sub-system 1305 is shown to be connected to a user interface 1301 to facilitate various input and output of voice and/or data provided to and received from the user. The baseband sub-system 1305 can also be connected to a memory 1303 that is configured to store data and/or instructions to facilitate the operation of the wireless device, and/or to provide storage of information for the user.

In the example wireless device 1300, outputs of the PAs 1340 are routed to their respective duplexers 1330. Such amplified and filtered signals can be routed to a primary antenna 1310 through an antenna switch module (ASM) 1320 for transmission. The PAs 1340 can implement hybrid quarter-wave impedance inverters to provide the advantages described herein.

Received signals are routed from the primary antenna 1310, through the ASM 1320, through the duplexers 1330, to the amplifiers 1350 (e.g., LNAs). For clarity, impedance matching components are not illustrated but are to be understood as being present along the transmission and receive paths as described herein.

One or more features of the present disclosure can be implemented with various cellular frequency bands as described herein. Examples of such bands are listed in Table 1. It will be understood that at least some of the bands can be divided into sub-bands. It will also be understood that one or more features of the present disclosure can be implemented with frequency ranges that do not have designations such as the examples of Table 1. It is to be understood that the term radio frequency (RF) and radio frequency signals refers to signals that include at least the frequencies listed in Table 1. In the table below, FDD refers to frequency-division duplexing, TDD refers to time-division duplexing, SDL refers to supplemental downlink, and SUL refers to supplemental uplink.

TABLE 1

| | | TX Frequency Range | |
|---|---|---|---|
| Band | Mode | (MHz) | RX Frequency Range (MHz) |
| B1 | FDD | 1920-1980 | 2110-2170 |
| B2 | FDD | 1850-1910 | 1930-1990 |
| B3 | FDD | 1710-1785 | 1805-1880 |
| B4 | FDD | 1710-1755 | 2110-2155 |
| B5 | FDD | 824-849 | 869-894 |
| B6 | FDD | 830-840 | 875-885 |
| B7 | FDD | 2500-2570 | 2620-2690 |
| B8 | FDD | 880-915 | 925-960 |
| B9 | FDD | 1749.9-1784.9 | 1844.9-1879.9 |
| B10 | FDD | 1710-1770 | 2110-2170 |
| B11 | FDD | 1427.9-1447.9 | 1475.9-1495.9 |
| B12 | FDD | 699-716 | 729-746 |
| B13 | FDD | 777-787 | 746-756 |
| B14 | FDD | 788-798 | 758-768 |
| B15 | FDD | 1900-1920 | 2600-2620 |
| B16 | FDD | 2010-2025 | 2585-2600 |
| B17 | FDD | 704-716 | 734-746 |
| B18 | FDD | 815-830 | 860-875 |
| B19 | FDD | 830-845 | 875-890 |
| B20 | FDD | 832-862 | 791-821 |
| B21 | FDD | 1447.9-1462.9 | 1495.9-1510.9 |
| B22 | FDD | 3,410-3,490 | 3,510-3,590 |
| B23 | FDD | 2000-2020 | 2180-2200 |
| B24 | FDD | 1626.5-1660.5 | 1525-1559 |
| B25 | FDD | 1850-1915 | 1930-1995 |
| B26 | FDD | 814-849 | 859-894 |
| B27 | FDD | 807-824 | 852-869 |
| B28 | FDD | 703-748 | 758-803 |
| B29 | FDD | N/A | 716-728 |
| B30 | FDD | 2305-2315 | 2350-2360 |
| B31 | FDD | 452.5-457.5 | 462.5-467.5 |
| B32 | FDD | N/A | 1452-1496 |
| B33 | TDD | 1900-1920 | 1900-1920 |
| B34 | TDD | 2010-2025 | 2010-2025 |
| B35 | TDD | 1850-1910 | 1850-1910 |
| B36 | TDD | 1930-1990 | 1930-1990 |
| B37 | TDD | 1910-1930 | 1910-1930 |
| B38 | TDD | 2570-2620 | 2570-2620 |
| B39 | TDD | 1880-1920 | 1880-1920 |
| B40 | TDD | 2300-2400 | 2300-2400 |
| B41 | TDD | 2496-2690 | 2496-2690 |
| B42 | TDD | 3400-3600 | 3400-3600 |
| B43 | TDD | 3600-3800 | 3600-3800 |
| B44 | TDD | 703-803 | 703-803 |
| B45 | TDD | 1447-1467 | 1447-1467 |
| B46 | TDD | 5150-5925 | 5150-5925 |
| B65 | FDD | 1920-2010 | 2110-2200 |
| B66 | FDD | 1710-1780 | 2110-2200 |
| B67 | FDD | N/A | 738-758 |
| B68 | FDD | 698-728 | 753-783 |
| B71 | FDD | 663-698 | 617-652 |
| n1 | FDD | 1920-1980 | 2110-2170 |
| n2 | FDD | 1850-1910 | 1930-1990 |
| n3 | FDD | 1710-1785 | 1805-1880 |
| n5 | FDD | 824-849 | 869-894 |
| n7 | FDD | 2500-2570 | 2620-2690 |
| n8 | FDD | 880-915 | 925-960 |
| n12 | FDD | 699-716 | 729-746 |
| n13 | FDD | 777-787 | 746-756 |
| n14 | FDD | 788-798 | 758-768 |
| n18 | FDD | 815-830 | 860-875 |
| n20 | FDD | 832-862 | 791-821 |
| n24 | FDD | 1626.5-1660.5 | 1525-1559 |
| n25 | FDD | 1850-1915 | 1930-1995 |
| n26 | FDD | 814-849 | 859-894 |
| n28 | FDD | 703-748 | 758-803 |
| n29 | SDL | N/A | 717-728 |
| n30 | FDD | 2305-2315 | 2350-2360 |
| n31 | FDD | 452.5-457.5 | 462.5-467.5 |
| n34 | TDD | 2010-2025 | 2010-2025 |
| n38 | TDD | 2570-2620 | 2570-2620 |
| n39 | TDD | 1880-1920 | 1880-1920 |
| n40 | TDD | 2300-2400 | 2300-2400 |
| n41 | TDD | 2496-2690 | 2496-2690 |
| n46 | TDD | 5150-5925 | 5150-5925 |
| n47 | TDD | 5855-5925 | 5855-5925 |
| n48 | TDD | 3550-3700 | 3550-3700 |
| n50 | TDD | 1432-1517 | 1432-1517 |
| n51 | TDD | 1427-1432 | 1427-1432 |
| n53 | TDD | 2483.5-2495 | 2483.5-2495 |
| n54 | TDD | 1670-1675 | 1670-1675 |
| n65 | FDD | 1920-2010 | 2110-2200 |
| n66 | FDD | 1710-1780 | 2110-2200 |
| n67 | SDL | N/A | 738-758 |
| n70 | FDD | 1695-1710 | 1995-2020 |
| n71 | FDD | 663-698 | 617-652 |
| n72 | FDD | 451-456 | 461-466 |
| n74 | FDD | 1427-1470 | 1475-1518 |
| n75 | SDL | N/A | 1432-1517 |
| n76 | SDL | N/A | 1427-1432 |
| n77 | TDD | 3300-4200 | 3300-4200 |
| n78 | TDD | 3300-3800 | 3300-3800 |
| n79 | TDD | 4400-5000 | 4400-5000 |
| n80 | SUL | 1710-1785 | N/A |
| n81 | SUL | 880-915 | N/A |
| n82 | SUL | 832- 862 | N/A |
| n83 | SUL | 703-748 | N/A |
| n84 | SUL | 1920-1980 | N/A |
| n85 | FDD | 698-716 | 728-746 |
| n86 | SUL | 1710-1780 | N/A |
| n89 | SUL | 824-849 | N/A |
| n90 | TDD | 2496-2690 | 2496-2690 |
| n91 | FDD | 832-862 | 1427-1432 |
| n92 | FDD | 832-862 | 1432-1517 |
| n93 | FDD | 880-915 | 1427-1432 |
| n94 | FDD | 880-915 | 1432-1517 |
| n95 | SUL | 2010-2025 | N/A |
| n96 | TDD | 5925-7125 | 5925-7125 |
| n97 | SUL | 2300-2400 | N/A |
| n98 | SUL | 1880-1920 | N/A |
| n99 | SUL | 1626.5-1660.5 | N/A |
| n100 | FDD | 874.4-880 | 919.4-925 |
| n101 | TDD | 1900-1910 | 1900-1910 |
| n102 | TDD | 5925-6425 | 5925-6425 |
| n104 | TDD | 6425-7125 | 6425-7125 |
| n105 | FDD | 663-703 | 612-652 |
| n106 | FDD | 896-901 | 935-940 |
| n109 | FDD | 703-733 | 1432-1517 |

### Terminology and Additional Embodiments

The present disclosure describes various features, no single one of which is solely responsible for the benefits described herein. It will be understood that various features described herein may be combined, modified, or omitted, as would be apparent to one of ordinary skill. Other combinations and sub-combinations than those specifically described herein will be apparent to one of ordinary skill, and are intended to form a part of this disclosure. Various methods are described herein in connection with various flowchart steps and/or phases. It will be understood that in many cases, certain steps and/or phases may be combined together such that multiple steps and/or phases shown in the flowcharts can be performed as a single step and/or phase. Also, certain steps and/or phases can be broken into additional sub-components to be performed separately. In some instances, the order of the steps and/or phases can be rearranged and certain steps and/or phases may be omitted entirely. Also, the methods described herein are to be understood to be open-ended, such that additional steps and/or phases to those shown and described herein can also be performed.

Some aspects of the systems and methods described herein can advantageously be implemented using, for example, computer software, hardware, firmware, or any combination of computer software, hardware, and firmware. Computer software can comprise computer executable code stored in a computer readable medium (e.g., non-transitory computer readable medium) that, when executed, performs the functions described herein. In some embodiments, computer-executable code is executed by one or more general purpose computer processors. A skilled artisan will appreciate, in light of this disclosure, that any feature or function that can be implemented using software to be executed on a general purpose computer can also be implemented using a different combination of hardware, software, or firmware. For example, such a module can be implemented completely in hardware using a combination of integrated circuits. Alternatively or additionally, such a feature or function can be implemented completely or partially using specialized computers designed to perform the particular functions described herein rather than by general purpose computers.

Multiple distributed computing devices can be substituted for any one computing device described herein. In such distributed embodiments, the functions of the one computing device are distributed (e.g., over a network) such that some functions are performed on each of the distributed computing devices.

Some embodiments may be described with reference to equations, algorithms, and/or flowchart illustrations. These methods may be implemented using computer program instructions executable on one or more computers. These methods may also be implemented as computer program products either separately, or as a component of an apparatus or system. In this regard, each equation, algorithm, block, or step of a flowchart, and combinations thereof, may be implemented by hardware, firmware, and/or software including one or more computer program instructions embodied in computer-readable program code logic. As will be appreciated, any such computer program instructions may be loaded onto one or more computers, including without limitation a general purpose computer or special purpose computer, or other programmable processing apparatus to produce a machine, such that the computer program instructions which execute on the computer(s) or other programmable processing device(s) implement the functions specified in the equations, algorithms, and/or flowcharts. It will also be understood that each equation, algorithm, and/or block in flowchart illustrations, and combinations thereof, may be implemented by special purpose hardware-based computer systems which perform the specified functions or steps, or combinations of special purpose hardware and computer-readable program code logic means.

Furthermore, computer program instructions, such as embodied in computer-readable program code logic, may also be stored in a computer readable memory (e.g., a non-transitory computer readable medium) that can direct one or more computers or other programmable processing devices to function in a particular manner, such that the instructions stored in the computer-readable memory implement the function(s) specified in the block(s) of the flowchart(s). The computer program instructions may also be loaded onto one or more computers or other programmable computing devices to cause a series of operational steps to be performed on the one or more computers or other programmable computing devices to produce a computer-implemented process such that the instructions which execute on the computer or other programmable processing apparatus provide steps for implementing the functions specified in the equation(s), algorithm(s), and/or block(s) of the flowchart(s).

Some or all of the methods and tasks described herein may be performed and fully automated by a computer system. The computer system may, in some cases, include multiple distinct computers or computing devices (e.g., physical servers, workstations, storage arrays, etc.) that communicate and interoperate over a network to perform the described functions. Each such computing device typically includes a processor (or multiple processors) that executes program instructions or modules stored in a memory or other non-transitory computer-readable storage medium or device. The various functions disclosed herein may be embodied in such program instructions, although some or all of the disclosed functions may alternatively be implemented in application-specific circuitry (e.g., ASICs or FPGAs) of the computer system. Where the computer system includes multiple computing devices, these devices may, but need not, be co-located. The results of the disclosed methods and tasks may be persistently stored by transforming physical storage devices, such as solid state memory chips and/or magnetic disks, into a different state.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list. The word “exemplary” is used exclusively herein to mean “serving as an example, instance, or illustration.” Any implementation described herein as “exemplary” is not necessarily to be construed as preferred or advantageous over other implementations.

The disclosure is not intended to be limited to the implementations shown herein. Various modifications to the implementations described in this disclosure may be readily apparent to those skilled in the art, and the generic principles defined herein may be applied to other implementations without departing from the spirit or scope of this disclosure. The teachings of the invention provided herein can be applied to other methods and systems, and are not limited to the methods and systems described above, and elements and acts of the various embodiments described above can be combined to provide further embodiments. Accordingly, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

1. A Doherty power amplifier for amplifying radio-frequency (RF) signals, the Doherty power amplifier comprising:
a splitter configured to receive an input signal and to provide a first signal associated with the input signal on a carrier amplification path and a second signal associated with the input signal on a peaking amplification path;
a carrier amplifier implemented on the carrier amplification path;
a peaking amplifier implemented on the peaking amplification path; and
a quarter-wave impedance inverter coupled to the peaking amplification path and the carrier amplification path and configured to provide a targeted phase shift to amplified signals, the quarter-wave impedance inverter comprising a first section configured to provide a first portion of the targeted phase shift and a second section configured to provide a second portion of the targeted phase shift, the first section including a transmission line, the second section including lumped elements coupled in series to the transmission line.

2. The Doherty power amplifier of claim 1, wherein the quarter-wave impedance inverter is implemented in a combiner configured to combine amplified signals from the carrier amplification path and amplified signals from the peaking amplification path.

3. The Doherty power amplifier of claim 1, wherein the first portion of the targeted phase shift is less than 50% of the targeted phase shift and the second portion of the targeted phase shift is greater than 50% of the targeted phase shift.

4. The Doherty power amplifier of claim 1, wherein the first portion of the targeted phase shift is greater than 30% and less than 40% of the targeted phase shift and the second portion of the targeted phase shift is greater than 60% and less than 70% of the targeted phase shift.

5. The Doherty power amplifier of claim 1, wherein a sum of the first portion of the targeted phase shift and the second portion of the targeted phase shift is equal to the targeted phase shift.

6. The Doherty power amplifier of claim 1, wherein the second section comprises a pi-network, T-network, or a combination of both.

7. The Doherty power amplifier of claim 1, wherein the quarter-wave impedance inverter is implemented using integrated passive device technology.

8. The Doherty power amplifier of claim 1 further comprising one or more impedance matching networks implemented on the peaking amplification path and one or more impedance matching networks implemented on the carrier amplification path.

9. The Doherty power amplifier of claim 1, wherein the quarter-wave impedance inverter is configured to phase shift amplified signals on the peaking amplification path.

10. The Doherty power amplifier of claim 1, wherein the quarter-wave impedance inverter is configured to phase shift amplified signals on the carrier amplification path.

11. A front end module comprising:
a packaging substrate; and
a Doherty power amplifier implemented on the packaging substrate, the Doherty power amplifier configured to amplify radio-frequency (RF) signals, the Doherty power amplifier including: a splitter configured to receive an input signal and to provide a first signal associated with the input signal on a carrier amplification path and a second signal associated with the input signal on a peaking amplification path; a carrier amplifier implemented on the carrier amplification path; a peaking amplifier implemented on the peaking amplification path; and a quarter-wave impedance inverter coupled to the peaking amplification path and the carrier amplification path and configured to provide a targeted phase shift to amplified signals, the quarter-wave impedance inverter comprising a first section configured to provide a first portion of the targeted phase shift and a second section configured to provide a second portion of the targeted phase shift, the first section including a transmission line, the second section including lumped elements coupled in series to the transmission line.

12. The front end module of claim 11, wherein the quarter-wave impedance inverter is implemented in a combiner configured to combine amplified signals from the carrier amplification path and amplified signals from the peaking amplification path.

13. The front end module of claim 11, wherein the first portion of the targeted phase shift is less than 50% of the targeted phase shift and the second portion of the targeted phase shift is greater than 50% of the targeted phase shift.

14. The front end module of claim 11, wherein the first portion of the targeted phase shift is greater than 30% and less than 40% of the targeted phase shift and the second portion of the targeted phase shift is greater than 60% and less than 70% of the targeted phase shift.

15. The front end module of claim 11, wherein a sum of the first portion of the targeted phase shift and the second portion of the targeted phase shift is equal to the targeted phase shift.

16. The front end module of claim 11, wherein the second section comprises a pi-network, T-network, or a combination of both.

17. The front end module of claim 11, wherein the quarter-wave impedance inverter is implemented using integrated passive device technology.

18. A wireless device comprising:
a primary antenna; and
a front end module coupled to the primary antenna, the front end module comprising a Doherty power amplifier configured to amplify radio-frequency (RF) signals, the Doherty power amplifier including: a splitter configured to receive an input signal and to provide a first signal associated with the input signal on a carrier amplification path and a second signal associated with the input signal on a peaking amplification path; a carrier amplifier implemented on the carrier amplification path; a peaking amplifier implemented on the peaking amplification path; and a quarter-wave impedance inverter coupled to the peaking amplification path and the carrier amplification path and configured to provide a targeted phase shift to amplified signals, the quarter-wave impedance inverter comprising a first section configured to provide a first portion of the targeted phase shift and a second section configured to provide a second portion of the targeted phase shift, the first section including a transmission line, the second section including lumped elements coupled in series to the transmission line.

19. The wireless device of claim 18, wherein the quarter-wave impedance inverter is implemented in a combiner configured to combine amplified signals from the carrier amplification path and amplified signals from the peaking amplification path.

20. The wireless device of claim 18, wherein the first portion of the targeted phase shift is less than 50% of the targeted phase shift and the second portion of the targeted phase shift is greater than 50% of the targeted phase shift.
